(19) United States
(12) Patent Application Publication
(10) Pub. No.: US 2018/0212116 A1
(43) Pub. Date: Jul. 26, 2018

(54) Durable LED Light Engine for Airfield Guidance Sign

(71) Applicant: Astronics DME LLC, Ft. Lauderdale, FL (US)

(72) Inventor: Sergio Bastiani, Fort Lauderdale, FL (US)

(21) Appl. No.: 15/873,860

(22) Filed: Jan. 17, 2018

Related U.S. Application Data
(60) Provisional application No. 62/446,958, filed on Jan. 17, 2017.

(51) Int. Cl. H01L 33/56; G09F 13/22; F21V 19/00; G08G 5/06; B64F 1/20; G09F 13/08

(52) U.S. Cl. CPC H01L 33/56; G09F 13/22; F21V 19/003; F21Y 2115/10; B64F 1/20; G09F 13/08; G08G 5/065

(57) ABSTRACT

An airfield guidance sign is provided. The airfield guidance sign has a housing with a display side. At least a portion of the display side is able to transmit light. For example, the display side may have a portion which is transparent or translucent. The airfield guidance sign includes an LED printed wiring assembly (“PWA”) mounted within the housing. The LED PWA has one or more LEDs configured to provide illumination to the display side of the housing. The illumination may be direct or indirect. The LEDs of the LED PWA are coated in an epoxy. For example, the LEDs may be coated in an optically-clear epoxy. In some embodiments, the entire LED PWA is coated in an epoxy. In some embodiments, portions of the LED PWA are coated in an epoxy that is not optically clear.

### CROSS-REFERENCE TO RELATED APPLICATIONS

The present application claims priority to U.S. Provisional Application No. 62/446,958, filed on Jan. 17, 2017, now pending, the disclosure of which is incorporated herein by this reference.

### FIELD OF THE DISCLOSURE

The present disclosure relates to airfield guidance lighting, and in particular, runway and taxiway signs.

### BACKGROUND OF THE DISCLOSURE

In the United States, airfield lighting is the subject of regulation by the Federal Aviation Administration (“FAA”). For example, runway and taxiway signs must conform to the “Specification for Runway and Taxiway Signs,” published by the FAA in Advisory Circular 150/5345-44K. Such specifications include environmental requirements such as operating temperature ranges, ability to withstand wind loads, exposure to rain/snow, and exposure to sunlight.

In order to withstand exposure to rain and snow, conventional signs utilize sealed LED light engines in order to prevent water from shorting the circuitry. Light engines are placed in enclosures that incorporate elaborate sealing mechanisms. Such enclosures are difficult and costly to manufacture, and are susceptible to failure over time. As such, there is a need for a less costly solution for meeting the regulatory guidelines related to exposure to rain, etc.

### BRIEF SUMMARY OF THE DISCLOSURE

An airfield guidance sign is provided. The airfield guidance sign has a housing with a display side. At least a portion of the display side is able to transmit light. For example, the display side may have a portion which is transparent or translucent. The airfield guidance sign includes an LED printed wiring assembly (“PWA”) mounted within the housing. The LED PWA has one or more LEDs configured to provide illumination to the display side of the housing. The illumination may be direct or indirect. The LEDs of the LED PWA are coated in an epoxy. For example, the LEDs may be coated in an optically-clear epoxy (e.g., an epoxy that attenuates the light from the LEDs by no more than 10%, if at all). In some embodiments, the entire LED PWA is coated in an epoxy. In some embodiments, portions of the LED PWA are coated in an epoxy that is not optically clear.

### DESCRIPTION OF THE DRAWINGS

For a fuller understanding of the nature and objects of the disclosure, reference should be made to the following detailed description taken in conjunction with the accompanying drawings, in which:

FIG. 1 depicts an a sign according to an embodiment of the present disclosure wherein the display side is not shown (in this way the LED PWA can be seen); and

FIG. 2 is a front elevation view of the sign of FIG. 1 and showing the display side.

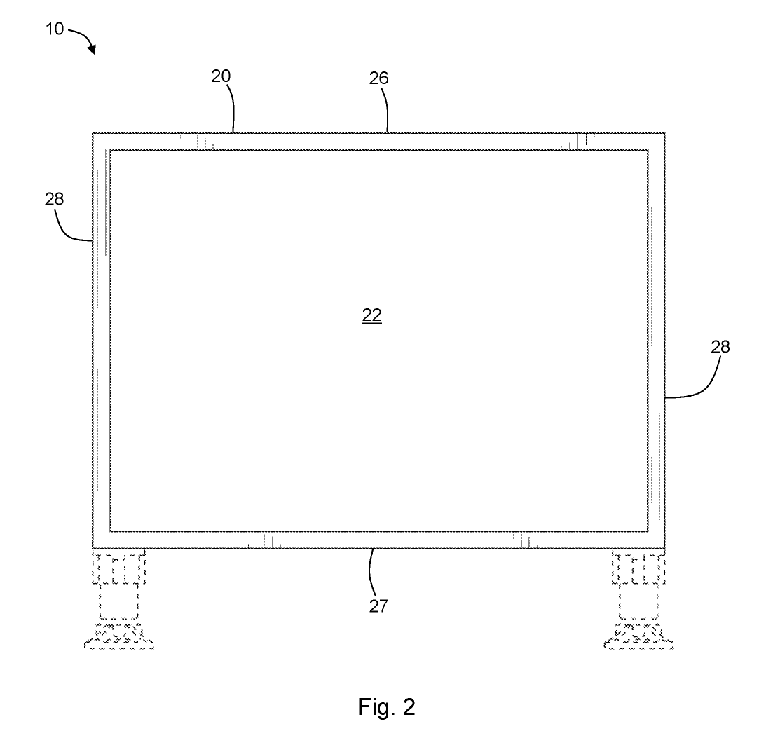

### DETAILED DESCRIPTION OF THE DISCLOSURE

The present disclosure may be embodied as an airfield guidance sign 10 having a housing 20. The housing 20 has a display side 22, at least a portion of which is translucent. In this way, the display side 22 can be backlit to display information. In an exemplary embodiment, the housing 20 has a display side 22, a back side 24, a top 26, a bottom 27, and two ends 28. Other shapes and sign configurations will be apparent in light of the present specification and are included within the present scope.

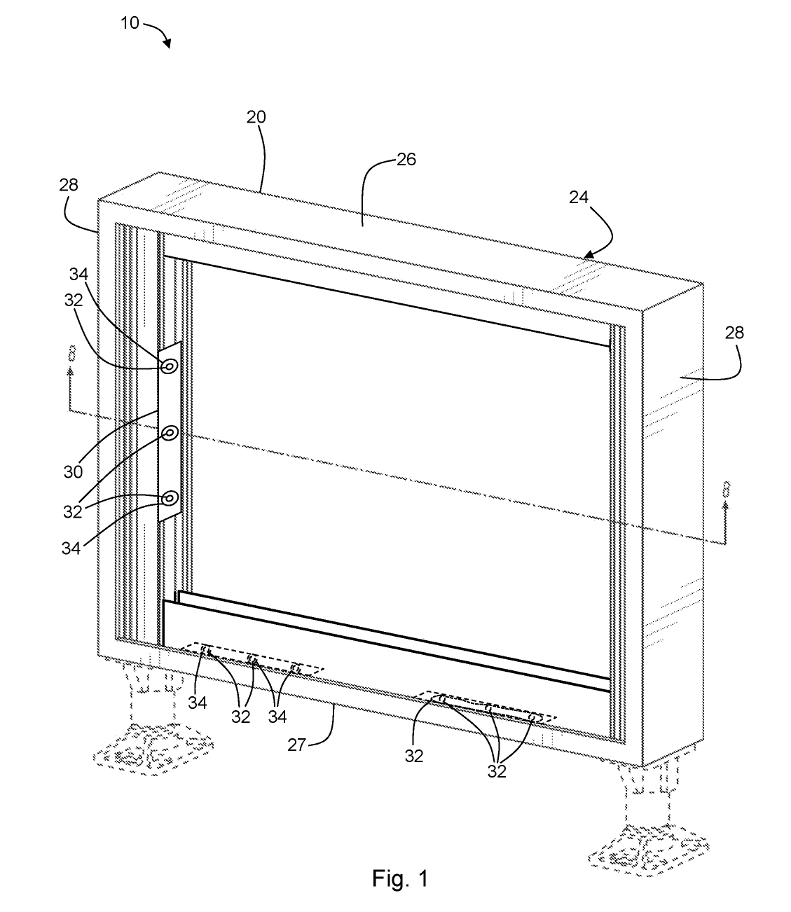

The sign 10 further includes an LED printed wiring assembly (“PWA”) 30 mounted within the housing 20. The LED PWA has one or more LEDs 32. The one or more LEDs 32 are configured to provide illumination (i.e., backlighting) to the display side 22 of the housing 20. For example, the one or more LEDs 32 may be disposed on a perimeter of the housing 20. In some embodiments, the LEDs are oriented towards the display side 22 such that light emanating from the one or more LEDs 32 is directed to the display side 22, though LEDs 32 are not necessarily oriented in this way. For example, in the embodiment depicted in FIG. 1, at least some of the LEDs 32 are arranged to provide indirect illumination for backlighting the display side 22. In some embodiments, the LED PWA has an LED light engine configured to provide power to the one or more LEDs 32.

The one or more LEDs 32 of the LED PWA 30 are coated in optically-clear epoxy 34. In this way, a water-tight seal is created by the epoxy coating, thereby preventing water from reaching the one or more LEDs 32 when the sign 10 is exposed to rain or snow, or otherwise exposed to water. By optically-clear, the light emanating from the one or more LEDs will be attenuated by 10% or less through the thickness of the epoxy coating (along an optical path from each LED 32 to the display side 22). In other words, the optically-clear epoxy coating 34 will affect the photometric output of the one or more LEDs 32 by less than, for example, 10%, 5%, 4%, 3%, 2%, 1%, etc. In some embodiments, such an optically-clear epoxy coating 34 will have little effect (e.g., less than 10%, 5%, 4%, 3%, 2%, 1%, etc.) on the chromaticity of the one or more LEDs 32.

In some embodiments, the LED PWA 30 is coated in epoxy and is therefore sealed against water. For example, the entire LED PWA 30 may be coated in an optically-clear epoxy. In some embodiments, the one or more LEDs 32 are coated in an optically-clear epoxy and a portion of the remainder of the LED PWA 30 is coated in an epoxy that is not optically clear. In some embodiments, the one or more LEDs 32 are coated in an optically-clear epoxy and the remainder of the LED PWA 30 is coated in an opaque epoxy. It should be noted, an one having skill in the art would recognize, that entirely coated in epoxy allows for lead wires, mounting studs, and/or other components of the LED PWA to traverse the coating as needed.

In some embodiments, the LED PWA 30 is mounted to one or more sides of the housing 20. For example, the LED PWA 30 may be mounted to one or more of the bottom 27, the top 26, and one or more ends 28. In a particular example, the LED PWA 30 is mounted to an end 28 such that the LED backlighting is provided to the display side 22 from the end 28. In another example, the LED PWA is mounted to both ends. For example, one or more LEDs may be mounted to a first end and one or more LEDs are mounted to a second of the two ends. In such an embodiments, each of the one or more LEDs is coated in an optically-clear epoxy and electrically connected by conducting wires which are not coated in epoxy. In this way, the LEDs can be moved relative to each other to better conform to the dimensions of the housing.

Because no separate enclosure is needed for the LED PWA, LED PWAs of the present disclosure can be mounted directly to the mechanical structure of the sign. In this way, the structure of the sign can be a heat sink for the LED PWA (e.g., dissipating heat generated by the LEDs and/or the LED light engine). Such a configuration advantageously reduces or eliminates the need for a separate heat sink.

Although the present disclosure has been described with respect to one or more particular embodiments, it will be understood that other embodiments of the present disclosure may be made without departing from the spirit and scope of the present disclosure.

We claim:

1. An airfield guidance sign, comprising:
a housing having a display side, at least a portion of the display side able to transmit light;
an LED printed wiring assembly (“PWA”) mounted within the housing, the LED PWA comprising one or more LEDs configured to provide illumination to the display side of the housing; and
wherein the one or more LEDs of the LED PWA are coated in optically-clear epoxy to create a water-tight seal.

2. The airfield guidance sign of claim 1, wherein the entire LED PWA is coated in epoxy.

3. The airfield guidance sign of claim 2, wherein the epoxy coating at least a portion of the LED PWA is not optically clear.

4. The airfield guidance sign of claim 1, wherein the least a portion of the display side is translucent.

5. The airfield guidance sign of claim 1, wherein the at least a portion of the display side is transparent.
